(19) United States
(12) Patent Application Publication
(10) Pub. No.: US 2012/0156825 A1
(43) Pub. Date: Jun. 21, 2012

(54) Transparent Contacts Organic Solar Panel by Spray

(75) Inventors: Jason Lewis, Lutz, FL (US); Jian Zhang, Tampa, FL (US); Xiaomei Jiang, Tampa, FL (US)

(73) Assignee: UNIVERSITY OF SOUTH FLORIDA, Tampa, FL (US)

(21) Appl. No.: 13/400,352

(22) Filed: Feb. 20, 2012

Related U.S. Application Data
(63) Continuation of application No. PCT/US2010/058732, filed on Dec. 2, 2010.
(60) Provisional application No. 61/265,963, filed on Dec. 2, 2009.

(51) Int. Cl. H01L 31/18

(52) U.S. Cl. 438/73; 257/E31.001

(57) ABSTRACT

A method of fabricating organic solar panels with transparent contacts. The method uses a layer-by-layer spray technique to create the anode layer. The method includes placing the substrate on a flat magnet, aligning a magnetic shadow mask over the substrate, applying photoresist to the substrate using spray photolithography, etching the substrate, cleaning the substrate, spin coating a tuning layer on substrate, spin coating an active layer of P3HT/PCBM on the substrate, spray coating the substrate with a modified PEDOT solution, and annealing the substrate.

### CROSS REFERENCE TO RELATED APPLICATIONS

This application is a continuation of co-pending International Application Serial Number PCT/US2010/058732 filed Dec. 2, 2010, which claims priority to U.S. Provisional Patent Application No. 61/265,963, filed Dec. 2, 2009, which is herein incorporated by reference.

### FIELD OF INVENTION

This invention relates to organic solar cells; in particular, to a method of fabricating a thin film organic solar module using a novel layer-by-layer spray technique.

### BACKGROUND

Organic solar cells (OSC) or organic photovoltaics (OPV) based on π-conjugated polymers (e.g. poly-3-hexylthiophene (P3HT)) and fullerene derivatives (e.g. [6,6]-phenyl C61 butyric acid methyl ester (PCBM)) have attracted attention over the past decades because they may provide a cost-effective route to wide use of solar energy for electric power generation.

These organic semiconductors have the advantage of being chemically flexible for material modifications, as well as mechanically flexible for the prospective of low-cost, large scale processing such as screen-printing or spraying on flexible substrates. The world's next generation of microelectronics may be dominated by “plastic electronics” and organic solar cells are expected to play an important role in these future technologies.

The photovoltaic process in organic solar cell devices consists of four successive possesses: light absorption, exciton dissociation, charge transport, and charge collection. Absorption of a photon creates an exciton (bounded electron-hole pair). The exciton diffuses to the interface of two different components, where exciton dissociation, or charge separation, occurs, followed by positive charges (holes) moving to the anodes and negative charges (electrons) to the cathode.

Several parameters determine the performance of a solar cell, namely, the open-circuit voltage (V_{oc}), short-circuit current (I_{sc}), and the so-called fill factor (FF). The overall power conversion efficiency η is defined as η=(FF)*(I_{Sc}V_{oc})/Pₘ. Over the past decade, OPV efficiency has been significantly improved to over five percent in single cell and one percent in submodules owing to a better understanding of device physics, optimization of device engineering, and developments of new materials.

However, most of such organic solar cell devices are developed in laboratories with fabrication processes involving spin-coating for the photoactive layer and the use of high vacuum to deposit the metal cathode. This conventional technique limits the real potential of organic solar cells in the commercial market due to the high cost of manufacturing using high vacuum.

Recently, world-wide research efforts have been made to develop transparent contacts based on modified Poly(3,4-ethylenedioxythiophene)poly(styrenesulfonate) (PEDOT:PSS) solution. Y. Liang et al., Development of New Semiconducting Polymers for High Performance Solar Cells, J. Am. Chem. Soc., V. 131, 56-57 (2009). For large scale production, screen printing (S. Shaheen et al., Fabrication of Bulk Heterojunction Plastic Solar Cells by Screen Printing, Appl. Phys. Lett., V. 79, 2996-2998 (2001)) and ink-jet printing (T. Aernouts et al., Polymer Based Organic Solar Cells Using Ink-Jet Printed Active Layers, App. Phys. Lett., Vol 92, 033306 (2008)) have been demonstrated mostly in OPV single cells.

Spraying methods, such as that described in Lim et al., have also been attempted. Lim et al., Spray-Deposited Poly(3,4-ethylenedioxythiophene:Poly(styrenesulfonate) Top Electrode for Organic Solar Cells, App. Phys. Lett., V. 93, 193301 (2008). However, such methods spray a thick layer of PEDOT:PSS to replace the need for metal cathode deposition using high vacuum. This thick layer of PEDOT:PSS sacrifices transparency, which is needed in certain application such as window technology. In fact, the thickness of the PEDOT:PSS layer produced by the method described in Lim et al. is over 2 μm. When thickness is over 1.26 μm, the transparency is below 1% (completely opaque), making Lim's method ineffective for producing transparent or even semi-transparent contacts for organic solar cells.

### SUMMARY OF INVENTION

The present invention includes a novel method to fabricate organic solar arrays with transparent contacts using a layer-by-layer spray technique. This provides for a balance between conductivity and transparency for the spray-on contacts.

In an embodiment, the method includes applying photoresist to a substrate by spray photolithography, spin coating a tuning layer on the substrate, spin coating an active layer coating on the substrate, spray coating the substrate with a modified PEDOT solution, and annealing the substrate.

The substrate may be an indium tin oxide (ITO) glass substrate, plastic, or cloth.

The active layer coating may be P3HT/PCBM.

The tuning layer may be cesium carbonate Cs₂CO₃.

In another embodiment, the method further includes cleaning the substrate with acetone and isopropanol prior to applying the photoresist.

In an additional embodiment, the method further includes etching the substrate, following application of the photoresist, and cleaning the etched substrate.

Etching may be completed using a solution of 20% HCl/7% HNO3 at about 130° C.

Cleaning the etched substrate may include sonicate cleaning the etched substrate and ozone cleaning the etched substrate. Sonicate cleaning may include sonicate cleaning with trichloroethylene (TCE) at about 50° C. for about twenty minutes, sonicate cleaning with acetone at about 50° C. for about twenty minutes, and sonicate cleaning with isopropanol at about 50° C. for about twenty minutes.

Spin coating the tuning layer may be completed at about 6000 rpm with an acceleration set to about 003 (330 rps) for about 60 seconds.

In a further embodiment, the method includes annealing the substrate on a hotplate at about 130° C. for about twenty minutes, following the application of the tuning layer.

The P3HT/PCBM may have a concentration of about 17 mg/ml.

Spin coating with P3HT/PCBM solution may be completed at about 700 rpm for about sixty seconds.

In another embodiment, the method further includes allowing the substrate to dry under a petre dish for about thirty minutes, and drying the substrate on a hotplate at about 110° C. for about ten minutes, following the application of the active layer.

The modified PEDOT solution may be prepared by adding between 5% and 8% of Dimethyl Sulfoxide (DMSO) by volume to a solution of undiluted PEDOT:PSS

Spray coating may be completed using an airbrush having a pressure setting of between 10 and 30 psi.

Spray coating may be completed while the substrate is on a hotplate heated to between 90° C. and 100° C.

Spray coating the substrate with modified PEDOT may be repeated and each layer of modified PEDOT may be allowed to dry before the next layer is applied.

In an additional embodiment, the method further includes annealing the device at about 120° C. for twenty minutes following spray coating.

### BRIEF DESCRIPTION OF THE DRAWINGS

For a fuller understanding of the invention, reference should be made to the following detailed description, taken in connection with the accompanying drawings, in which:

FIG. 1A is a flowchart of the fabrication process of an organic solar cell according to an embodiment of the present invention.

FIGS. 1B through 1F are diagrams illustrating the fabrication process of an inverted organic solar cell.

FIG. 2 is a flowchart of the patterning process using spray photolithography according to an embodiment of the present invention.

FIG. 3 is a flowchart illustrating the steps to add a tuning layer using spin coating according to an embodiment of the present invention.

FIG. 4 is a flowchart illustrating the steps to add an active layer using spin coating according to an embodiment of the present invention.

FIG. 5 is a flowchart illustrating the steps to add an anode layer using spray according to an embodiment of the present invention.

### DETAILED DESCRIPTION OF THE PREFERRED EMBODIMENT

In the following detailed description of the preferred embodiments, reference is made to the accompanying drawings, which form a part hereof, and within which are shown by way of illustration specific embodiments by which the invention may be practiced. It is to be understood that other embodiments may be utilized and structural changes may be made without departing from the scope of the invention.

The present invention includes a novel method to fabricate organic solar arrays with transparent contacts using a layer-by-layer spray technique. This provides for a balance between conductivity and transparency for the spray-on contacts.

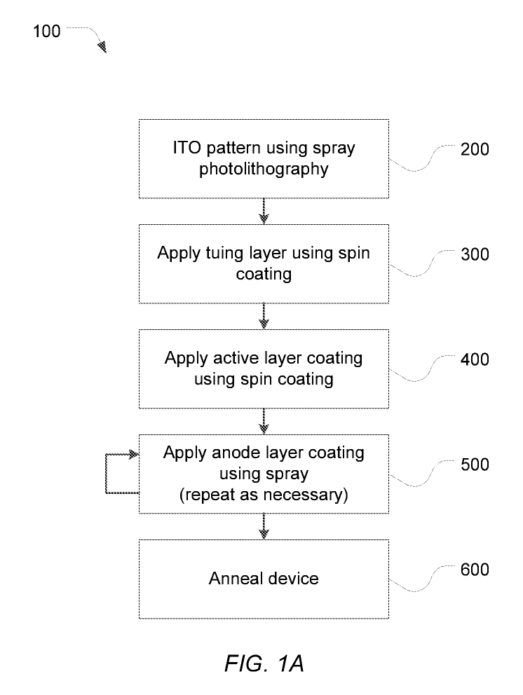

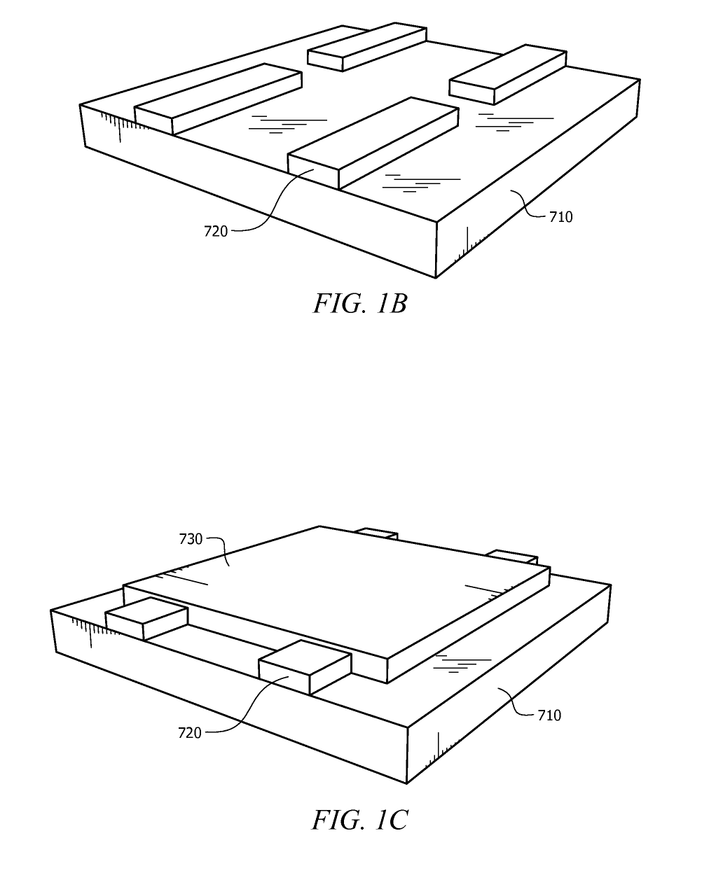

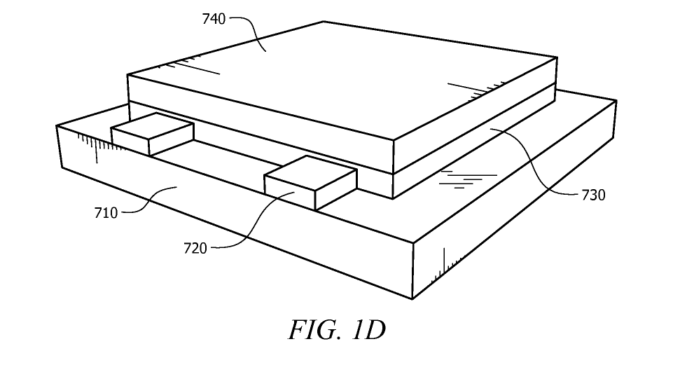

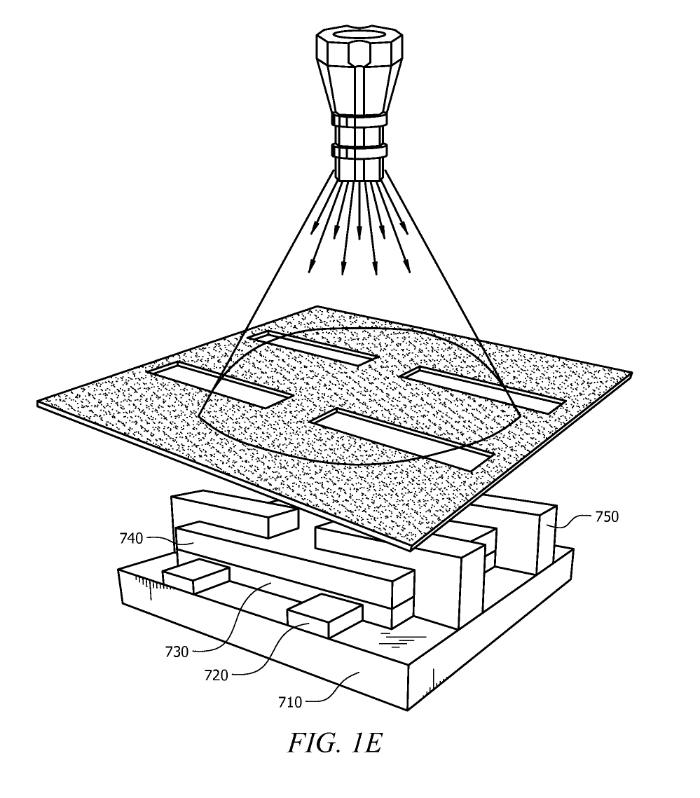

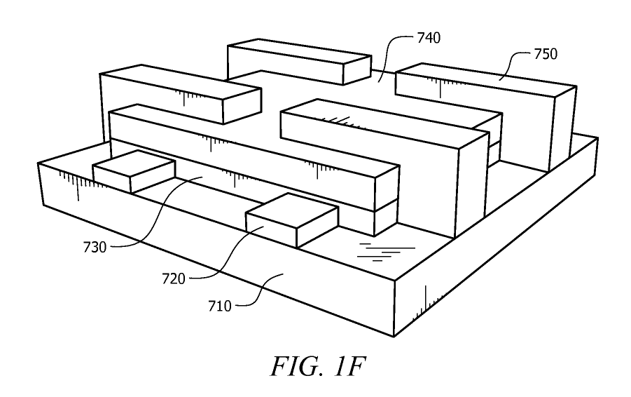

The fabrication process 100 is illustrated generally in the flowchart of FIG. 1A and in the diagrams in FIGS. 1B through 1F. In operation 200, substrate 710 is patterned with photoresist 720 using spray photolithography. The result is shown in FIG. 1B. Then, in operation 300, spin coating is used to add tuning layer 730. The patterned substrate with tuning layer 730 is shown in FIG. 1C. Then, in operation 400, spin coating is used to add active layer 740. The result is shown in FIG. 1D. In operation 500, anode layer 750 is applied to the substrate using spray, as shown in FIG. 1E. This operation is repeated, as necessary, for desired thickness. Each layer is allowed to dry before the next layer is applied. Finally, once the desired number of layers has been added, the device is annealed, in operation 600. The completed inverted organic solar cell is shown in FIG. 1F.

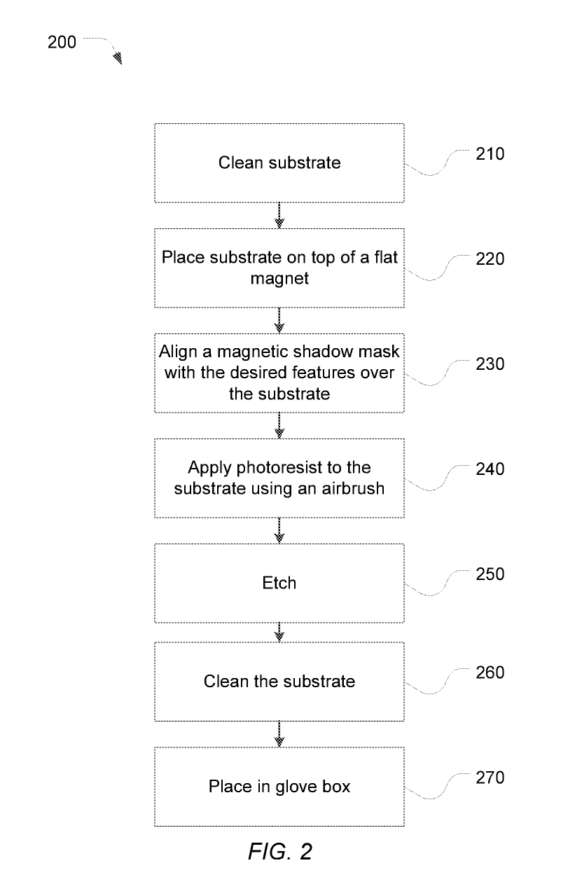

A more detailed embodiment of the fabrication process is described in the flowcharts of FIGS. 2 through 5.

Patterning is completed using spray photolithography. Unlike conventional photolithography, there is no need for an optical mask and to develop patterns when using spray photolithography. Process for spray patterning 200 is illustrated in the flowchart of FIG. 2. In operation 210, the substrate is cleaned. The substrate may be any type of substrate including glass, plastic, or cloth. In operation 220, the substrate is placed on top of a flat magnet and, in operation 230, a magnetic shadow mask is aligned over the substrate. The shadow mask may include any desired shape. Next, in operation 240, photoresist is applied to the substrate using an airbrush. An airbrush with a fine tip and a pressure setting between 10 to 40 psi is preferred. Etching is then completed in an aqua regia solution in operation 250. Such etching may be completed in a solution of 20 HCL/7% HNO3 at 90° C. to 130° C. The substrate is then cleaned, in operation 260, and placed in a glove box, in operation 270.

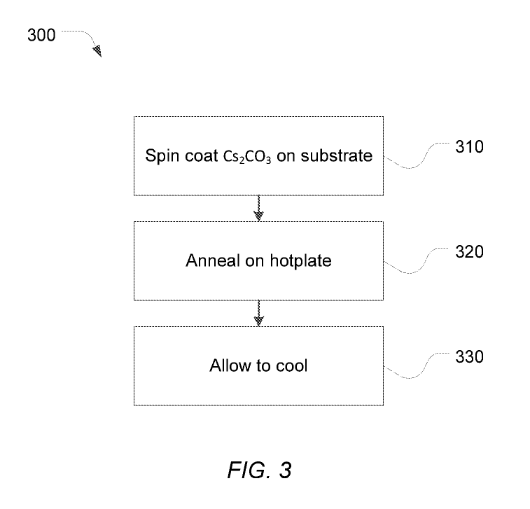

Process for spin coating to add a tuning layer 300 is illustrated in the flowchart of FIG. 3. In operation 310, a layer of cesium carbonate (Cs₂CO₃) is applied to the patterned substrate using spin coating. Such tuning layer may alternatively be zinc oxide (ZnO), self assembled molecules, or anything known in the art to tune the ITO work function. The substrate is then annealed on a hotplate, in operation 320, and then allowed to cool, in operation 330. The preferable temperature of the hotplate is between 150° C. and 170° C.

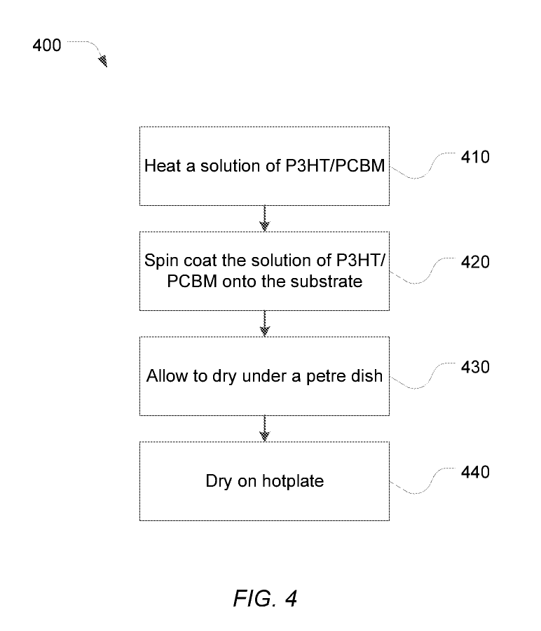

Process for spin coating to add an active layer coating 400 is illustrated in the flowchart of FIG. 4. In operation 410, a solution of P3HT/PCBM in Dichlorobenzene is heated. The solution preferably has a concentration of 10 to 20 mg/mL and is heated at 50° C. to 60° C. for about 24 hours. The solution is then applied to the substrate by spin coating, in operation 420. Spin coating is preferably completed at 400 to 700 rpm for about 60 seconds. The substrate is then allowed to dry under a petre dish. This process may take about 12 to 24 hours. Alternatively, the substrate can be allowed to dry for a shorter period of time (e.g. about 30 minutes) under a petre dish, as in operation 430, and then annealed on a hotplate, as in operation 440. This will take about 10 minutes at 110° C.

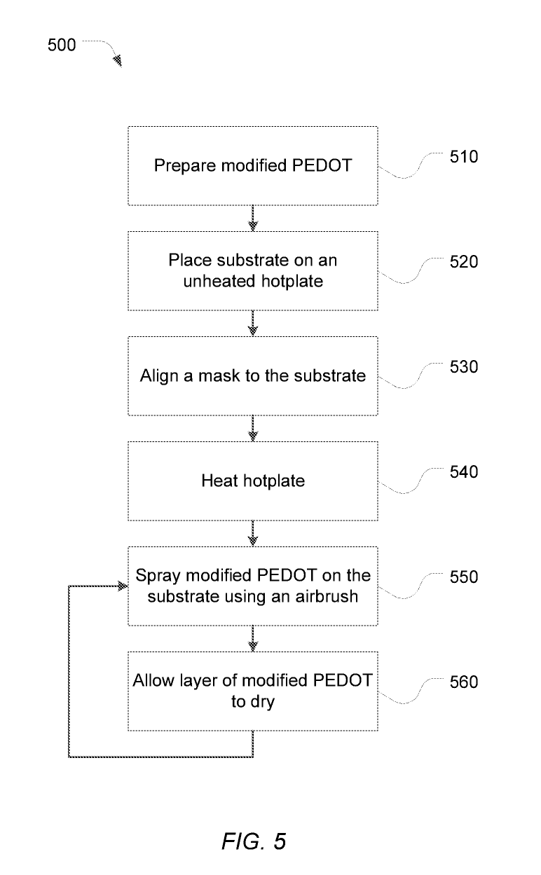

Process for using spray to apply an anode layer coating 500 is illustrated in the flowchart of FIG. 5. In order to create a semi-transparent contact and at the same time maintain acceptable contact resistance, a modified solution of PEDOT was created and used. A solution of PEDOT:PSS with 5-8% by volume DMSO is preferred. In operation 510, the modified PEDOT solution is prepared. In operation 520, the substrate is placed on an unheated hotplate, and, in operation 530, a mask is aligned to the substrate. Then, the hotplate is heated, in operation 540. A hotplate temperature of 90 to 100° C. is preferred. In operation 550, using an airbrush, the modified PEDOT is sprayed onto the substrate. The pressure setting is preferably between 10 and 30 psi. After the modified PEDOT dries another layer can be added by spray. The modified PEDOT should be applied as very light discontinuous coats. Layers can continue to be added until the anode layer coating reaches the desired thickness.

Once the desired number of layers has been added, the device is annealed.

### Exemplary Embodiment

In an exemplary embodiment, an ITO/glass substrate was cleaned with acetone and isopropanol. The substrate was then placed on top of a flat magnet and a magnetic shadow mask with desired features was aligned over the substrate. Positive photoresist (Shipley 1813) was applied using an airbrush having a fine tip. The airbrush had a pressure setting of <10 psi. Etching was then completed using a solution of 20% HCL/7% HNO₃ at 130° C. depending on solution volume. The substrate was sonicate cleaned with TCE, acetone, and isopropanol at 50° C. for 20 minutes each and ozone cleaned for 30 minutes. The patterned substrate was then placed in a glove box.

A layer of Cs₂CO₃ solution was applied to the patterned substrate using spin coating. First, Cs₂CO₃ was added to a solution of 2-ethoxyethanol at a ratio of 2 mg/ml and stirred for one hour. Spin coating was completed at 6000 rpm with an acceleration set to 003 (330 rps) for 60 seconds. The substrate was then dried on a hotplate at 130° C. for 20 minutes and then allowed to cool.

A solution of P3HT/PCBM with a concentration of 17 mg/ml was stirred for 24 hours at 50° C. In another example, the solution had a concentration of 20 mg/ml and was stirred for one hour at 55° C. The solution was then applied to the substrate by spin coating at 700 rpm for 60 seconds. After drying under a petre dish for 30 minutes, the substrate was dried on a hotplate at 110° C. for 10 minutes.

A modified PEDOT solution was prepared by adding five percent by volume of DMSO to a solution of undiluted PEDOT:PSS and then sonicating the solution at 50° C. for 10 minutes before use. The substrate was placed on an unheated hotplate, and a stainless steel shadow mask was aligned to the substrate. Then, the hotplate was heated to 95° C. Using an airbrush with a fine tip, nitrogen gas (N₂) as the carrier gas, and a pressure setting of 20 psi, the modified PEDOT was sprayed onto the substrate. Spray coating was accomplished by holding the tip of the airbrush three to seven centimeters away from the substrate and moving the airbrush at a constant steady speed. Additional layers of modified PEDOT were then added allowing each layer to dry before the next layer was applied. Not allowing the each layer to dry may cause the material to stick to itself and not the active layer resulting in a very rough surface morphology.

Layers were added until the layer reached a thickness of about 0.5 μm. The device was then annealed at 120° C. for twenty minutes.

It will be seen that the advantages set forth above, and those made apparent from the foregoing description, are efficiently attained and since certain changes may be made in the above construction without departing from the scope of the invention, it is intended that all matters contained in the foregoing description or shown in the accompanying drawings shall be interpreted as illustrative and not in a limiting sense.

It is also to be understood that the following claims are intended to cover all of the generic and specific features of the invention herein described, and all statements of the scope of the invention which, as a matter of language, might be said to fall there between.

What is claimed is:

1. A method of fabricating organic solar panels with transparent contacts, comprising:
applying photoresist to a substrate by spray photolithography;
spin coating a tuning layer on the substrate;
spin coating an active layer coating on the substrate;
spray coating the substrate with a modified PEDOT solution; and
annealing the substrate.

2. The method of claim 1, wherein the substrate is an ITO glass substrate.

3. The method of claim 1, wherein the substrate is plastic.

4. The method of claim 1, wherein the substrate is cloth.

5. The method of claim 1, wherein the tuning layer is Cs₂CO₃.

6. The method of claim 1, wherein in the active layer coating is P3HT/PCBM.

7. The method of claim 1, further comprising:
cleaning the substrate with acetone and isopropanol prior to applying the photoresist.

8. The method of claim 1, further comprising:
etching the substrate, following application of the photoresist; and
cleaning the etched substrate.

9. The method of claim 8, wherein etching is completed using a solution of 20% HCl/7% HNO3 at about 130° C.

10. The method of claim 8, wherein cleaning the etched substrate comprises:
sonicate cleaning the etched substrate; and
ozone cleaning the etched substrate.

11. The method of claim 8, wherein sonicate cleaning further comprises:
sonicate cleaning with TCE at about 50° C. for about twenty minutes;
sonicate cleaning with acetone at about 50° C. for about twenty minutes; and
sonicate cleaning with isopropanol at about 50° C. for about twenty minutes.

12. The method of claim 1, wherein the spin coating the tuning layer is completed at about 6000 rpm with acceleration set to about 330 rps for about 60 seconds.

13. The method of claim 1, further comprising:
annealing the substrate on a hotplate at about 130° C. for about twenty minutes, following the application of the tuning layer.

14. The method of claim 1, wherein the P3HT/PCBM has a concentration of about 17 mg/ml.

15. The method of claim 1, wherein the spin coating with P3HT/PCBM solution is completed at about 700 rpm for about sixty seconds.

16. The method of claim 1, further comprising:
allowing the substrate to dry under a petre dish for about thirty minutes, and
drying the substrate on a hotplate at about 110° C. for about ten minutes, following the application of the active layer.

17. The method of claim 1, wherein the modified PEDOT solution is prepared by adding between 5% and 8% of DMSO by volume to a solution of undiluted PEDOT:PSS

18. The method of claim 1, wherein spray coating is completed using an airbrush having a pressure setting of between 10 and 30 psi.

19. The method of claim 1, wherein spray coating is completed while the substrate is on a hotplate heated to between 90° C. and 100° C.

20. The method of claim 1, wherein spray coating the substrate with modified PEDOT is repeated and each layer of modified PEDOT is allowed to dry before the next layer is applied.

21. The method of claim 20, wherein layers of modified PEDOT are added until the thickness of the modified PEDOT is about 0.5 μm.

22. The method of claim 1, wherein the thickness of the modified PEDOT does not exceed 1.26 μm.

23. The method of claim 1, further comprising:
annealing the device at about 120° C. for twenty minutes following spray coating.
